(19) United States
(12) Patent Application Publication
(10) Pub. No.: US 2007/0229129 A1
(43) Pub. Date: Oct. 4, 2007

(54) PLL CIRCUIT

(75) Inventor: Kouichi NAKAGAWA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 11/691,182

(22) Filed: Mar. 26, 2007

(30) Foreign Application Priority Data
Mar. 28, 2006 (JP) 2006-088519

(51) Int. Cl. H03L 7/06

(52) U.S. Cl. 327/156

(57) ABSTRACT

A PLL (Phase Locked Loop) circuit having a main circuit and a dummy circuit is provided which is capable of reducing a phase offset between a reference clock and a feedback clock. In the PLL circuit, a phase of each of the reference clock and feedback clock each received through either of a pair of input terminals is compared by a phase frequency detector to output an UP or DOWN signal and phases of reference clocks received through two input terminals are compared by a dummy phase frequency detector to output a dummy UP or dummy DOWN signal. According to a differential in output voltage between a first charge pump of the main circuit and a second charge pump of the dummy circuit, current sources are controlled to charge or discharge the first and second charge pumps. The current sources are used to charge and discharge the second charge pump while being not used for charge and discharge of the first charge pump.

### BACKGROUND OF THE INVENTION

1. Field of the Invention

The present invention relates to a PLL (Phase Locked Loop) circuit made up of a main circuit including a main charge pump and of a dummy circuit including a dummy charge pump.

The present application claims priority of Japanese Patent Application No. 2006-088519 filed on Mar. 28, 2006, which is hereby incorporated by reference.

2. Description of the Related Art

As semiconductor manufacturing technology progresses in recent years, circuit components are scaled down and made finer and, therefore, influences by variations in characteristic of an individual transistor making up an LSI (Large Scale Integrated Circuit) on each circuit component become important. One of the influences is a known problem of occurrence of a phase offset between a reference clock and a feedback clock caused by errors in manufacturing current sources of each of a main circuit and a dummy circuit making up a PLL circuit, which is made up of the main circuit including a main charge pump (hereinafter referred simply as a “CP”) and of the dummy circuit including a dummy CP.

FIG. 7 is a diagram showing an example of a PLL circuit having, in addition to a conventional main circuit, a dummy circuit, which chiefly includes a PFD (Phase Frequency Detector) 11, a CP 12, an LF (Low Pass Filter) 13, a PFD 14, a CP 15, an LF 16, a VCO (Voltage Controlled Oscillator) 17, a DIV (Diver) 18, and an OPAMP (Operational Amplifier) 19. Out of them, the PFD 11, CP 12, and LF 13 make up the dummy circuit and the PFD 14, CP 15, and LF 16 make up the main circuit.

The PFD 11 is configured to compare phases of reference clocks received through a pair of input terminals and to input, according to a phase difference caused by circuit unbalance or a like, a dummy UP signal or a dummy DOWN signal. The CP 12 boosts its output voltage responsive to the dummy UP signal and lowers its output voltage responsive to the dummy DOWN signal. The LF 13 removes high-frequency components contained in an output from the CP 12 to output a control signal “Vcnt dummy”.

The PFD 14 compares a phase of each of a reference clock REF and a feedback clock FBK each being received through either of a pair of input terminals and outputs, according to a phase difference, an UP signal or a DOWN signal. The CP 15 boosts its output voltage responsive to the UP signal and lowers its output voltage responsive to the DOWN signal. The LF 16 removes high-frequency components contained in an output from the CP 15 to output a control signal “Vcnt”.

The VCO 17 generates a signal whose frequency increases or decreases according to magnitude of a voltage of a control signal “Vcnt”. The DIV 18 divides a frequency of an output signal from the VCO 17 at a specified rate and outputs the divided signal as a feedback clock FBK. The OP AMP 19 serves as a differential amplifier and is configured to output a control signal “PBIAS” whose level is changed depending on a magnitude relationship between a control signal “Vcnt dummy” output from the dummy circuit and a control signal “Vcnt” output from the main circuit.

The dummy circuit is configured to imitate a circuit arrangement, a wiring length, or a like of the main circuit, for example, on an LSI. The PFD 11 in the dummy circuit compares phases of the reference clocks REF received through a pair of input terminals and generates a dummy UP signal or dummy DOWN signal according to a difference in a wiring length, parasitic capacitance between the two inputs, or a like, which causes an output voltage from the CP12 to be changed. The PFD 14 in the main circuit compares a phase of each of a reference clock REF and feedback clock FBK and generates an UP signal and a DOWN signal, which causes a change of an output voltage from the CP15 and each of the UP signal and DOWN signal contains a component having the same magnitude as the dummy UP signal and dummy DOWN signal according to a difference in a wiring length and/or in parasitic capacitance between two inputs including the reference clock REF and feedback clock FBK.

Then, in the OP AMP 19, an output error caused by the difference in a wiring length and/or in parasitic capacitance between the two inputs in the PFD 14 of the main circuit is removed by controlling a current source (not shown) of each of the CP 12 of the dummy circuit and the CP 15 of the main circuit using a control signal “PBIAS” generated by calculation of a differential between the control signal “Vcnt dummy” output from the dummy circuit and the control signal “Vcnt” output from the main circuit.

FIG. 8 is a diagram explaining control of the dummy circuit CP 12 and main circuit CP 15 in the conventional PLL circuit shown in FIG. 7. An output voltage from the CP 12 is controlled by activating a switch (not shown) using an output from the PFD 11 of the dummy circuit to control a current source 21A on a flowing-in side of the CP12 and a current source 21B on a drawing side of the CP 12 in the dummy circuit and an output voltage from the CP15 is controlled by activating a switch (not shown) using an output from the PFD 14 of the main circuit to control a current source 22A on a flowing-in side and a current source 22B on a drawing side of the CP 15 in the main circuit. Then, an output error caused by the difference in a wiring length, parasitic capacitance, or a like between the two inputs in the PFD 14 of the main circuit is removed by activating the current sources 21A and 21B and current sources 22A and 22B using a control signal “PBIAS” generated by calculation by the OPAMP 19 of a differential between a signal obtained by filtering an output from the CP 12 via the LF 13 and a signal obtained by filtering an output from the CP 15 via the LF 16 to control an influent current from the current source on the flowing-in side to the CP12 or from the current source on the flowing-in side to the CP 15 and to control a flowing-out current from the CP 12 to the current source 21B on the drawing side or from the CP 15 to the current source 22B on the drawing side.

However, the conventional PLL circuit as shown in FIG. 7 has a problem. That is, if there are differences in a current supplying capability, magnitude of a leakage current, or a like caused by errors in manufacturing among the current sources 21A and 21B and the current sources 22A and 22B, it is impossible to remove an output error, caused by the above differences, between the control signal “Vcnt dummy” and the control signal “Vcnt” and, as a result, a phase offset occurs between the reference clock REF and the feedback clock FBK.

To solve this problem, a charge-pump type phase frequency detector is disclosed in Patent Reference 1 (Japanese Patent Application Laid-open No. 2005-323028) which is capable of canceling a leakage charge caused by parasitic capacitance in a charging and discharging means making up a main charge pump and/or non-linearity of their devices. In the disclosed charge-pump type phase frequency detector, a main charge pump 981 is made up of a current source 973 and a discharging means 932 and 942 and a sub-charge pump 982 is made up of a current source 974 and discharging means 952 and 962 (see paragraph [0023] in the Patent Reference). However, in the disclosed detector, the main charge pump 981 of the main charge pump and the current source 973 of the sub-charge pump 982 each are separately and individually constructed and, therefore, the above problem associated with the conventional PLL circuit remains unsolved.

Also, another PLL circuit is disclosed in Patent Reference 2 (Japanese Patent Application Laid-open No. 2004-215105) which is capable of sufficiently suppressing a reference leakage and of setting a loop band to be wide to the limit, thus providing a PLL oscillator that can reduce a phase noise. The disclosed PLL circuit has a charge pump 2 and another charge pump 6 to convert an error signal output from the phase frequency detector 1 into a current (see paragraphs [0028] to [0031] in the Patent Reference). The Patent Reference 2 describes that the charge pump 2 has a variable current source circuit 12, however, configurations of the charge pump 2 are the same as those of the charge pump 6 [see paragraph (0034)] and it means, therefore, that the charge pump 6 also has a variable current source and that the current sources for the two charge pumps are separately and individually provided, which does not solve the above problem associated with the conventional PLL circuit Also, still another PLL circuit is disclosed in Patent Reference 3 (Japanese Patent Application Laid-open No. Hei 11-027141) which has first and second charge pumps, the first one performing charging and discharging of a filter capacitor by using UP and DOWN signals and the second one comparing a current charging voltage with a target charging voltage and, if the current charging voltage is lower than the target charging voltage, the second charge pump is activated to perform a high-speed charging. In this case, also, the first and second charge pumps are connected separately and individually to each of current sources (see FIGS. 1 to 3). Thus, the separate current source is provided individually to each of the charge pumps and, therefore, the above problem associated with the conventional PLL remains unsolved.

Also, a substrate voltage generating circuit is disclosed in Patent Reference 4 (Japanese Patent Publication No. Hei 07-032238), which is capable of suppressing floating of a voltage by adding a backup charge pump to a charge pump. By providing the backup charge pump to a plurality of main charge pumps each generating a substrate voltage and detecting a source voltage in a source voltage detecting circuit 2 and, if magnitude of source power exceeds an ordinary use range, the backup charge pump that was in a state of quiescent operation and a driving circuit are made to operate to greatly expand capability of the substrate voltage generating circuit and, therefore, the floating of a voltage can be prevented (see 3^{rd} to 8^{th} row in a right column in page 6 in the Patent Reference). However, the Patent Reference 4 describes only that, if magnitude of a source voltage exceeds an ordinary use range, the backup charge pump is made to operate to improve capability of the substrate voltage generating circuit and, therefore, it does not serve to solve the above problem associated with the conventional PLL circuit.

Furthermore, a PLL circuit is disclosed in Patent Reference 5 (Japanese Patent Application Laid-open No. 2005-123944) in which a phase offset between a reference clock and a feedback clock is reduced. In the PLL circuit, circuit configurations of the dummy circuit 16 having a dummy phase frequency detector and a dummy charge pump 17 are the same as a main circuit having a phase frequency detector 11 and a charge pump 12 [see paragraph (0022)]. No special description of the dummy charge pump 17 and the circuit charge pump 12 is not provided, however, it is supposed that the dummy charge pump 17 and the circuit charge pump 12 have the same circuit configurations as those of the charge pump 32 of the conventional circuit (see FIG. 8) which is operated by a current source (not shown). This means that each of the dummy charge pump 17 and the charge pump 12 has a separate current source. Thus, the separate current source is provided separately and individually to each of the dummy charge pump 17 and the charge pump 12 and, therefore, the above problem associated with the conventional PLL remains still unsolved.

Therefore, the conventional PLL circuit made up of the dummy circuit having the dummy phase frequency detector and the dummy charge pump and of the main circuit having the phase frequency detector and the charge pump has the problem in that, if there is circuit unbalance such as a difference in current supplying capability of each current source or magnitude of a leakage current caused by a manufacturing error such as variations in performance of transistors making up the dummy circuit and main circuit, occurrence of a phase offset between the reference clock REF and feedback clock FBK is unavoidable.

### SUMMARY OF THE INVENTION

In view of the above, it is an object of the present invention to provide a PLL circuit made up of a main circuit having a phase frequency detector and a charge pump and of a dummy circuit having a dummy phase frequency detector and a dummy charge pump, which is capable of reducing a phase offset between a reference clock and a feedback clock caused by an error in manufacturing current sources.

According to a first aspect of the present invention, there is provided a PLL circuit including:

a first circuit which includes a first phase frequency detecting unit to output an up signal or a down signal according to a result from comparison of a phase of each of a reference clock and a feedback clock each being received through either of a pair of input terminals, a first low pass filter to filter a voltage output from a first charge pump, and a voltage controlled oscillating unit to generate a feedback clock with a frequency corresponding to a voltage output from the first low pass filter;

a second circuit which includes a second phase frequency detecting unit configured to imitate the first phase frequency detecting unit and to output a dummy up signal or dummy down signal according to a result from comparison of phases of reference clocks each being received through either of a pair of input terminals and a second low pass filter to filter a voltage output from a second charge pump configured to imitate the first charge pump; and

a charge pump circuit which includes a first charge pump whose output voltage is boosted or lowered by an up signal or down signal fed from the first phase frequency detecting unit, a second charge pump configured to imitate the first charge pump and whose output voltage is boosted or lowered by a dummy up signal or dummy down signal fed from the second phase frequency detecting unit, a current source on a flowing-in side whose operation is made possible by the up signal or dummy up signal, and a current source on a drawing side whose operation is made possible by the down signal or dummy down signal, wherein a current flowing out from the current source on the flowing-in side to the first charge pump or the second charge pump or a current flowing in the current source on the drawing side from the first charge pump or from the second charge pump is controlled according to a differential between an output from the first low pass filter and an output from the second low pass filter.

In the foregoing, a preferable mode is one that wherein includes a calculating unit to calculate a differential between an output from the first low pass filter and an output from the second low pass filter, wherein either of the current source on the flowing-in side or the current source on the drawing side is made to operate according to an output signal from the calculating unit.

Also, a preferable mode is one wherein, the charge pump circuit is controlled so that the current source on the flowing-in side and the current source on the drawing side are allowed to be used by the second charge pump during a period while the first charge pump is not operating.

Also, a preferable mode is one that wherein includes a frequency dividing unit on the voltage controlled oscillating unit side, which divides a frequency of an output from the voltage controlled oscillating unit to generate the feedback clock.

Also, a preferable mode is one wherein the first phase frequency detecting unit compares a phase of a reference clock and the feedback clock to output an up signal or down signal.

Furthermore, a preferable mode is one that wherein includes a phase inverting unit connected between a supplying unit of the reference clock and the second phase frequency detecting unit and wherein the dummy charge pump is made to operate at a fall edge of the reference clock.

With the above configuration, while the main circuit is not operating, the current source of the main circuit is made to operate as the current source for the dummy circuit and, therefore, unlike in the case where a separate current source is used for each of the main circuit and dummy circuit, occurrence of a phase offset between a reference clock and a feedback clock caused by a manufacturing error of the current sources can be prevented.

### BRIEF DESCRIPTION OF THE DRAWINGS

The above and other objects, advantages, and features of the present invention will be more apparent from the following description taken in conjunction with the accompanying drawings in which:

FIG. 1 is a block diagram showing configurations of a PLL circuit of an embodiment of the present invention;

FIG. 2 is a diagram showing a state in which current sources are shared by a main circuit and a dummy circuit in the PLL circuit of the embodiment of the present invention;

FIG. 3 is a diagram explaining connection of current sources when the main circuit is operating in the PLL circuit according to the embodiment of the present invention;

FIG. 4 is a diagram explaining connection of current sources when the dummy circuit is operating in the PLL circuit according to the embodiment of the present invention;

FIG. 5 is a diagram showing an example of an operating time chart in the PLL circuit according to the embodiment of the present invention;

FIG. 6 is a diagram showing another example of an operating time chart in the PLL circuit according to the embodiment of the present invention;

FIG. 7 is a diagram showing an example of configurations of a conventional PLL circuit having a main circuit and a dummy circuit; and

FIG. 8 is a diagram explaining control of the dummy circuit and main circuit in the conventional PLL circuit shown in FIG. 7.

### DETAILED DESCRIPTION OF THE PREFERRED EMBODIMENTS

Best modes of carrying out the present invention will be described in further detail using various embodiments with reference to the accompanying drawings. The PLL circuit of the present invention is made up of a main circuit having a first PFD (Phase Frequency Detector) to output an UP or DOWN signal according to a result from comparison of a phase of each of a reference clock and a feedback clock each being received through either of a pair of input terminals, a first LF (Low Pass filter) to filter an output voltage of a first charge pump, and a VCO (Voltage Controlled Oscillator) to generate a feedback clock having a frequency corresponding to an output voltage from the first LF, and of a dummy circuit having a second PFD configured to imitate the first PFD and to output a dummy UP signal or dummy DOWN signal according to a result from comparison of phases of reference clocks received through a pair of input terminals and, a second LF to filter an output voltage from a second charge pump configured to imitate the first charge pump, and a charge pump circuit having the first charge pump whose output voltage is boosted or lowered according to an UP signal or DOWN signal fed from the second PFD, second charge pump configured to imitate the first charge pump and whose output voltage is boosted or lowered according to the dummy UP signal or dummy DOWN signal fed from the second PFD, a current source on a flowing-in side, a current source on a drawing side, wherein an operation of the current source on the flowing-in side is made possible by an UP signal or dummy UP signal and an operation of the current source on the drawing side is made possible by a DOWN signal or dummy DOWN signal, and wherein a current flowing out from the current source on the flowing-in side to the first and second charge pumps or a current flowing in from the first and second charge pumps to the current source on the drawing side is controlled according to a differential between outputs from the first LF and second LF.

### Embodiment

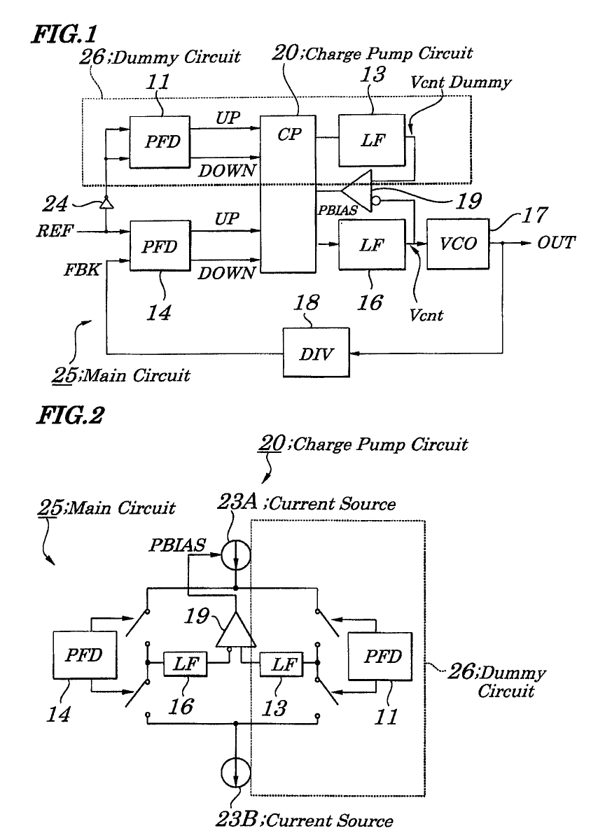

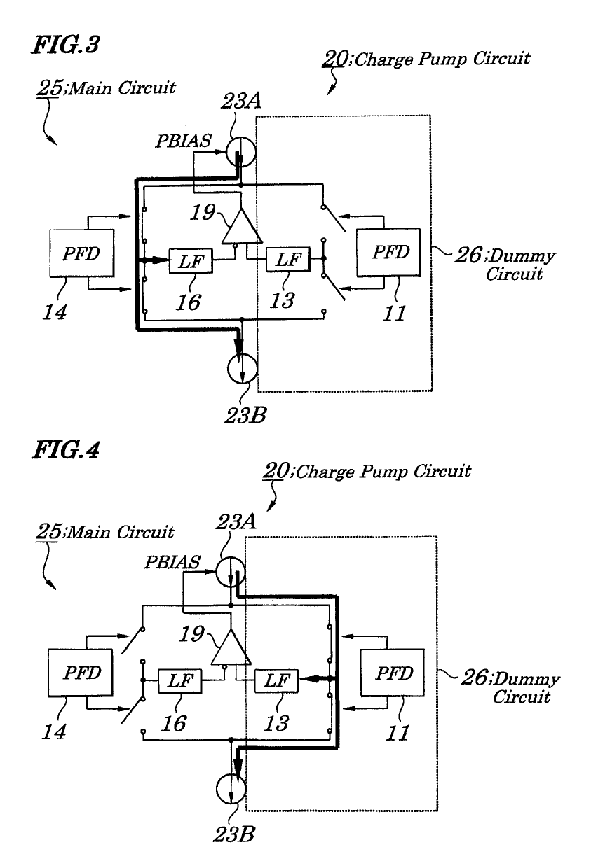

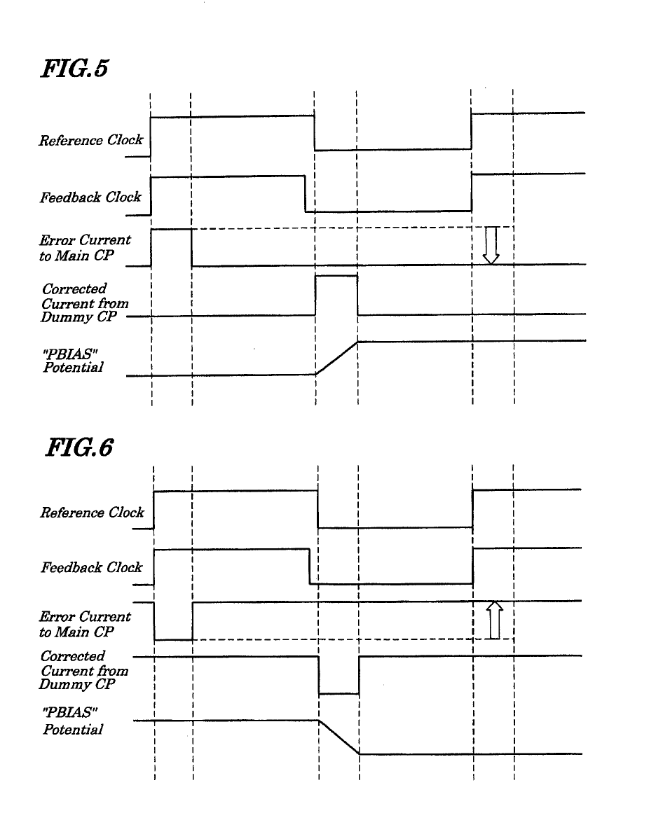

FIG. 1 is a block diagram showing configurations of a PLL circuit of an embodiment of the present invention. FIG. 2 is a diagram showing a state in which current sources are shared by a main circuit and a dummy circuit in the PLL circuit of the embodiment. FIG. 3 is a diagram explaining connection of current sources when the main circuit is operating in the PLL circuit according to the embodiment. FIG. 4 is a diagram explaining connection of current sources when the dummy circuit is operating in the PLL circuit according to the embodiment. FIG. 5 is a diagram showing an example of an operating time chart in the PLL circuit according to the embodiment. FIG. 6 is a diagram showing another example of an operating time chart in the PLL circuit according to the embodiment.

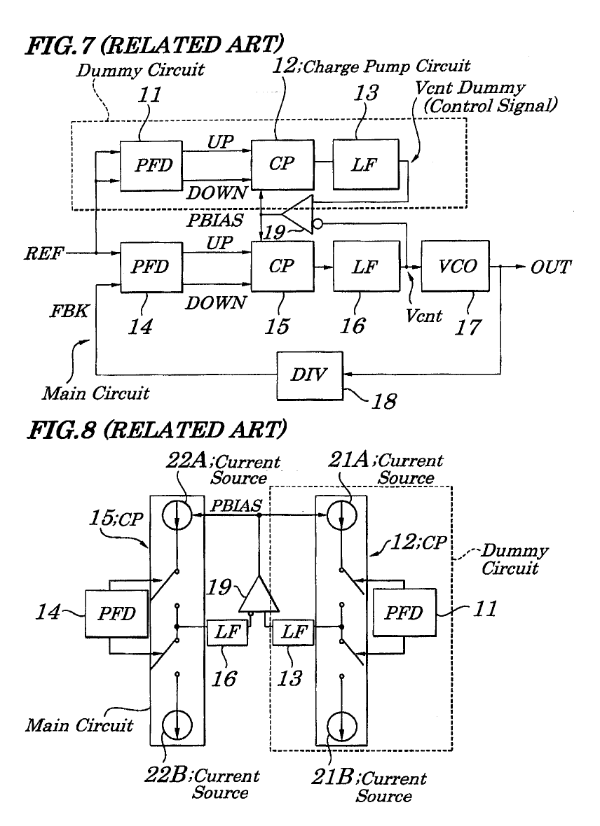

The PLL circuit of the embodiment, as shown in FIG. 1, includes a PFD 11, an LF 13, a PFD 14, an LF 16, a VCO (Voltage Controlled Oscillator) 17, a DIV (Divider) 18, an OPAMP (Operational Amplifier) 19, a charge pump circuit 20, and an inverter 24. Configurations of the PFD 11, LF13, PFD14, LF16, VCO17, DIV18, and OPAMP 19, are the same as those shown in FIG. 7, except that a reference clock REF is inverted through the inverter 24 and the inverted reference clock REF is applied to the PFD 11. The PFD 11 and LF 13 make up the dummy circuit 26 and the PFD 14 and LF 16 make up the main circuit 25, however, the charge pump circuit 20 is shared by the main circuit 25 and dummy circuit 26. The charge pump circuit 20 includes a dummy charge pump (not shown) and a main charge pump (not shown) and a current source on a flowing-in side (not shown) and a current source on a drawing side (not shown). Both the current sources on the flowing-in side and on the drawing side are connected to the dummy charge pump when the dummy circuit 26 including the dummy charge pump is activated and to the main charge pump when the main circuit 25 including the main charge pump is activated.

Operations of the PLL circuit shown in FIG. 1 are described. In the main circuit 25, a reference clock REF and a feedback clock FBK, each being received through either of a pair of input terminals, are compared and, according to a result from the comparison, an UP signal or DOWN signal is output. The LF 16 is configured to filter a voltage output from a first charge pump to output a signal from which a high-frequency component is removed. The VCO 17 generates a signal with a frequency corresponding to an output from the LF 16. The DIV 18 divides a frequency of a voltage from the VOC 17 at a specified dividing rate and generates a feedback FBK.

In the dummy circuit 26, the PFD 11 is constructed by imitating the PFD 14 and compares reference clocks REF, each being received through either of a pair of input terminals and, according to a result from the comparison, outputs a dummy UP or dummy DOWN signal. The LF 13 filters a voltage from the second charge pump and outputs a signal from which a high-frequency component is removed.

In the charge pump circuit 20, an output voltage of the first charge pump is boosted or lowered by an UP signal or DOWN signal from the PFD 14. The second charge pump is constructed by imitating circuit configurations of the first charge pump and whose output voltage is boosted or lowered by a dummy UP signal or dummy DOWN signal from the PFD 11. The charge pump circuit 20 has a current source (not shown) on the flowing-in side and another current source (not shown) on the drawing side. The current source on the flowing-in side becomes operable responsive to an UP signal or a dummy UP signal and the current source on the drawing side becomes operable responsive to a DOWN signal or a dummy DOWN signal. The OPAMP 19 controls, according to a difference between an output from the LF 16 and an output from the LF 11, a current flowing out from the current source on the flowing-in side to the first charge pump or the second charge pump or a current flowing in the current source on the drawing side from the first charge pump or the second charge pump.

As shown in FIG. 2, in the charge pump circuit 20 having the main circuit 25 including a main charge pump (not shown) and the dummy circuit 26 including a dummy charge pump (not shown) in the PLL circuit of the embodiment, a current source 23A on the flowing-in side and a current source 23B on the drawing side are shared by the main circuit 25 and dummy circuit 26. Also, in the charge pump circuit 20, the current source 23A and current source 23B are controlled by a control signal “PBIAS” resulting from calculation, to be performed by the OPAMP 19, of a differential between a voltage output from the main charge pump through the LF 16 and a voltage output from the dummy charge pump through the LF 13. Also, while the main circuit 25 is operating, the main charge pump is connected to the current sources 23A and 23B according to an output from the PFD 14 and while the dummy circuit 26 is operating, the dummy charge pump is connected to the current sources 23A and 23B according to an output from the PFD 11 and a voltage is output from the main charge pump and dummy charge pump.

FIG. 3 shows a state of connection of current sources 23A and 23B when the main circuit 25 is operating, in which the main charge pump is connected, according to an output from the PFD 14, to the current sources 23A and 23B and a current flows in and out the main charge pump by control on the current sources 23A and 23B according to a control signal “PBIAS”, however, the dummy charge pump is not connected to the current sources 23A and 23B and no current flows in or out the dummy charge pump.

FIG. 4 shows a state of connection of current sources 23A and 23B when the dummy circuit 26 is operating, in which the dummy charge pump is connected, according to an output from the PFD 11, to the current sources 23A and 23B and a current flows in and out the dummy charge pump by control on the current sources 23A and 23B according to a control signal “PBIAS”, however, the main charge pump is not connected to the current sources 23A and 23B and no current flows in or out the main charge pump.

Hereinafter, operations of the PLL circuit of the embodiment when the dummy charge pump is activated at a fall edge of a reference clock are described by using time charts in FIGS. 5 and 6.

FIG. 5 shows an operation of the PLL circuit when a flow-out current from the current source 23A on the flowing-in side is larger than a flow-in current from the current source 23B on the drawing side. In this case, though, at the initial timing, edges of reference clocks REF and feedback clock FBK rise at the same time, since a flow-in current of the current source 23A on the flowing-in side is larger than a flow-out current, an error current is flown in the main charge pump. However, at a fall edge of a reference clock REF, a corrected current is flown in from the dummy charge pump using the same current source and, as a result, a potential of the control signal “PBIAS” output from the OPAMP 19 is boosted, which causes a decrease in a current of the current source 23A on the flowing-in side and, therefore, at the last timing, an error signal to be flown in the main charge pump becomes 0 (zero).

FIG. 6 shows an operation of the PLL circuit when a flow-in current to the current source 23B on the drawing side is larger than a flow-out current from the current source 23A on the flowing-in side. In this case, though, at the initial timing, edges of reference clocks REF and feedback clock FBK rise at the same time, since a flow-out current of the current source 23B on the drawing side is larger than a flow-in current, an error current is drawn from the main charge pump. However, at the fall edge of a reference clock REF, a corrected current is drawn from the dummy charge pump using the same current source and, as a result, a potential of the control signal “PBIAS” output from the OPAMP 19 is lowered, which causes an increase in a current of the current source 23A on the flowing-in side and, therefore, at the last timing, an error signal to be drawn from the main charge pump becomes 0 (zero).

Thus, according to the PLL circuit of the embodiment, the current source of the main circuit can be operated as the current source for the dummy circuit while the main circuit is not operating and, unlike in the case where a separate current source is used for each of the main and dummy circuits, a phase offset between a reference clock and feedback clock can be reduced without being affected by a manufacturing error such as variations in characteristics of an individual transistor making up the current source.

It is apparent that the present invention is not limited to the above embodiments but may be changed and modified without departing from the scope and spirit of the invention. For example, individual connection of transistors making up the main circuit, dummy circuit, and charge pump circuit may be selected freely depending on use purpose.

Additionally, the PLL circuit of the present invention can be applied to various electrical components to be embedded in PLL circuits.

What is claimed is:

1. A PLL (Phase Locked Loop) circuit comprising:
a first circuit which comprises a first phase frequency detecting unit to output an up signal or a down signal according to a result from comparison of a phase of each of a reference clock and feedback clock each being received through either of a pair of input terminals, a first low pass filter to filter a voltage output from a first charge pump, and a voltage controlled oscillating unit to generate a feedback clock with a frequency corresponding to a voltage output from said first lowpass filter;
a second circuit which comprises a second phase frequency detecting unit configured to imitate said first phase frequency detecting unit and to output a dummy up signal or dummy down signal according to a result from comparison of phases of reference clocks each being received through either of a pair of input terminals and a second low pass filter to filter a voltage output from a second charge pump configured to imitate said first charge pump; and
a charge pump circuit which comprises a first charge pump whose output voltage is boosted or lowered by an up signal or down signal fed from the said first phase frequency detecting unit, a second charge pump configured to imitate said first charge pump and whose output voltage is boosted or lowered by a dummy up signal or dummy down signal fed from said second phase frequency detecting unit, a current source on a flowing-in side whose operation is made possible by said up signal or dummy up signal, and a current source on a drawing side whose operation is made possible by said down signal or dummy down signal, wherein a current flowing out from said current source on said flowing-in side to said first charge pump or said second charge pump or a current flowing in said current source on said drawing side from said first charge pump or from said second charge pump is controlled according to a differential between an output from said first low pass filter and an output from said second low pass filter.

2. The PLL circuit according to claim 1, further comprising a calculating unit to calculate a differential between an output from said first low pass filter and an output from said second low pass filter, wherein either of said current source on said flowing-in side or said current source on said drawing side is made to operate according to an output signal from said calculating unit.

3. The PLL circuit according to claim 1, wherein, said charge pump circuit is controlled so that said current source on said flowing-in side and said current source on said drawing side are allowed to be used by said second charge pump during a period while said first charge pump is not operating.

4. The PLL circuit according to claim 1, further comprising a frequency dividing unit on said voltage controlled oscillating unit side, which divides a frequency of an output from said voltage controlled oscillating unit to generate said feedback clock.

5. The PLL circuit according to claim 4, wherein said first phase frequency detecting unit compares a phase of a reference clock and said feedback clock to output an up signal or down signal.

6. The PLL circuit according to claim 1, still further comprising a phase inverting unit connected between a supplying unit of said reference clock and said second phase frequency detecting unit and wherein said dummy charge pump is made to operate at a fall edge of said reference clock.

7. A PLL (Phase Locked Loop) circuit comprising:
a first circuit which comprises a first phase frequency detecting means to output an up signal or a down signal according to a result from comparison of a phase of each of a reference clock and feedback clock each being received through either of a pair of input terminals, a first low pass filter to filter a voltage output from a first charge pump, and a voltage controlled oscillating means to generate a feedback clock with a frequency corresponding to a voltage output from said first low pass filter;
a second circuit which comprises a second phase frequency detecting means configured to imitate said first phase frequency detecting means and to output a dummy up signal or dummy down signal according to a result from comparison of phases of reference clocks each being received through either of a pair of input terminals and a second low pass filter to filter a voltage output from a second charge pump configured to imitate said first charge pump; and
a charge pump circuit which comprises a first charge pump whose output voltage is boosted or lowered by an up signal or down signal fed from the said first phase frequency detecting means, a second charge pump configured to imitate said first charge pump and whose output voltage is boosted or lowered by a dummy up signal or dummy down signal fed from said second phase frequency detecting means, a current source on a flowing-in side whose operation is made possible by said up signal or dummy up signal, and a current source on a drawing side whose operation is made possible by said down signal or dummy down signal, wherein a current flowing out from said current source on said flowing-in side to said first charge pump or said second charge pump or a current flowing in said current source on said drawing side from said first charge pump or from said second charge pump is controlled according to a differential between an output from said first low pass filter and an output from said second low pass filter.

8. The PLL circuit according to claim 7, further comprising a calculating means to calculate a differential between an output from said first low pass filter and an output from said second low pass filter, wherein either of said current source on said flowing-in side or said current source on said drawing side is made to operate according to an output signal from said calculating means.

9. The PLL circuit according to claim 7, wherein, said charge pump circuit is controlled so that said current source on said flowing-in side and said current source on said drawing side are allowed to be used by said second charge pump during a period while said first charge pump is not operating.

10. The PLL circuit according to claim 7, further comprising a frequency dividing means on said voltage controlled oscillating means side, which divides a frequency of an output from said voltage controlled oscillating means to generate said feedback clock.

11. The PLL circuit according to claim 10, wherein said first phase frequency detecting means compares a phase of a reference clock and said feedback clock to output an up signal or down signal.

12. The PLL circuit according to claim 7, still further comprising a phase inverting means connected between a supplying means of said reference clock and said second phase frequency detecting means and wherein said dummy charge pump is made to operate at a fall edge of said reference clock.
